(19) United States
(12) Patent Application Publication
(10) Pub. No.: US 2026/0198344 A1
(43) Pub. Date: Jul. 9, 2026

(54) HARD MASK FOR BOTTOM-UP VIA PLATING

(71) Applicant: Intel Corporation, Santa Clara, CA (US)

(72) Inventors: Jeremy D. ECTON, Gilbert, AZ (US); Micah David ARMSTRONG, Leeds, AL (US); Rengarajan SHANMUGAM, Tempe, AZ (US); Helme A. CASTRO DE LA TORRE, Gilbert, AZ (US); Brandon C. MARIN, Gilbert, AZ (US); Suddhasattwa NAD, Chandler, AZ (US); Jason M. GAMBA, Gilbert, AZ (US)

(21) Appl. No.: 19/015,371

(22) Filed: Jan. 9, 2025

(51) Int. Cl. H01L 23/498; H01L 21/48; H10D 1/20; H10D 1/60

(52) U.S. Cl. CPC H10W 70/635; H10D 1/20; H10D 1/60; H10W 70/095

(57) ABSTRACT

Embodiments disclosed herein include an apparatus with a substrate that comprises a glass layer. In an embodiment, a via is provided through a thickness of the substrate, and the via has a first aspect ratio. In an embodiment, the via directly contacts the substrate. In an embodiment, a layer is around an end of the via, and the layer extends down a partial length of a sidewall of the via. In an embodiment, a cavity is provided through the thickness of the substrate, and the cavity has a second aspect ratio that is smaller than the first aspect ratio. In an embodiment, a component is in the cavity, and a fill layer is around the component in the cavity.

### BACKGROUND

Glass cores for package substrates are an attractive option due to the increased stiffness and planarity that they provide compared to existing organic cores. However, the brittle nature of glass provides several challenges with respect to manufacturing. One issue that is present for glass cores is the high stress that is generated by vias that are formed through the glass core (i.e., through glass vias (TGVs)). With traditional plating, a seed layer is provided along the sidewalls of the via opening, and the via is plated out from the sidewalls. This provides a strong mechanical coupling between the vias and the glass core. During thermal cycling, the via expands more than the glass core, and this generates a high stress in the glass core. The high stress may result in cracking or other defects that significantly impact the reliability of the glass core.

### BRIEF DESCRIPTION OF THE DRAWINGS

FIG. 1 is a cross-sectional illustration of a package substrate with a glass core with a component filled cavity that further includes TGVs that are formed with a bottom-up plating process, in accordance with an embodiment.

FIGS. 2A-2I are cross-sectional illustrations depicting a process for forming a glass core with a component filled cavity that further includes TGVs that are formed with a bottom-up plating process, in accordance with an embodiment.

FIGS. 3A-3C are zoomed in cross-sectional illustrations depicting a portion of a TGV that is plated with a bottom-up plating process, in accordance with an embodiment.

FIG. 4 is a process flow describing a process for forming a via with a bottom-up plating process without plating an adjacent cavity, in accordance with an embodiment.

FIG. 5 is a cross-sectional illustration of an electronic system that comprises a package substrate with a glass core that includes a component filled cavity with bottom-up plated vias adjacent to the cavity, in accordance with an embodiment.

FIG. 6 is a schematic of a computing device built in accordance with an embodiment.

### EMBODIMENTS OF THE PRESENT DISCLOSURE

Described herein are glass substrates with through glass vias (TGVs) that are plated with a bottom-up process with an adjacent cavity, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide stiffness and/or improved planarity compared to organic cores. However, the strong mechanical coupling between the through glass vias (TGVs) and the glass core results in significant stress being induced in the glass core during thermal cycling. As such, cracking or other damage to the glass core may occur. This negatively impacts the reliability of such glass cores. Further, the high aspect ratios of the TGVs make it difficult to form void-free TGVs in a cost-effective manner. For example, an atomic layer deposition process may be used. However, atomic layer deposition is a slow and expensive process, and such a process may not be compatible with high volume manufacturing environments.

Accordingly, embodiments disclosed herein include a bottom-up plating process in order to form the TGVs. In a bottom-up plating process, an electrically conductive layer is provided across a bottom of the via opening. The plating proceeds in a vertical direction up through the via opening. In such an embodiment, the interface between the TGV and the sidewall has a weaker mechanical coupling than traditional plating from a seed layer along the sidewall of the via opening. For example, the TGV may have a sidewall that contacts the sidewall of the via opening in some locations and is spaced away from the sidewall of the via opening by a gap (e.g., an air gap) at other locations. The gaps may have a width between the sidewall of the via opening and the TGV that is in the submicron scale. As such, the electrical conductivity is not significantly impacted while also allowing for improved mechanical reliability of the glass core.

In some embodiments, large cavities are also needed through glass core. The large cavities may be used to house additional components, such as passive electrical components (e.g., capacitors, inductors, resistors, etc.), active components (e.g., dies, memory, etc.), electrical routing (e.g., bridge substrates, etc.), or the like. Components may be discrete components, or the components may be integrated into the cavity as part of the overall process flow. Typically, the cavity is formed in parallel with the via openings for the TGVs. However, since a component will be added to the cavity, the cavity needs to be free from plating. This is difficult in a bottom-up plating process.

One approach may use a mask that spans (or tents) across the cavity to prevent plating in the cavity. However, such large tenting distances lead to manufacturing complexities and can provide poor process reliability. Alternatively, the cavity may be plated and subsequently etched back to re-open the cavity. However, this leads to process complexity by adding in an etching process that may result in chunks of copper falling into the etch bath. Additionally, throughput is reduced due to low copper etch rates. Another approach may be to plug the cavity (e.g., with an organic dielectric). However, plugging the core at this point in the process flow is challenging due to the risk of cracking the glass core during polishing (e.g., chemical mechanical polishing (CMP)) that is needed to planarize the plug.

Accordingly, embodiments disclosed herein include a selective deposition process that is able to selectively deposit a mask layer at the bottom of the cavities, while leaving the bottom of the via openings free from the mask layer. The selectivity of the deposition is enable by leveraging the aspect ratio differences between the cavity and the via openings. For example, an aspect ratio (height:width) of the via openings may be approximately 10:1 or greater, or approximately 20:1 or greater, and an aspect ratio of the cavity may be up to approximately 10:1, or up to approximately 5:1.

In an embodiment, the mask layer may be selectively deposited with a physical vapor deposition (PVD) process. The mask layer may include an electrically insulating material. For example, the mask layer may comprise silicon and oxygen (e.g., SiO₂), silicon and nitrogen (e.g., Si₃N₄), titanium and oxygen (e.g., TiO₂), tantalum and oxygen (e.g., Ta₂O₅), aluminum and oxygen (e.g., Al₂O₃), boron and nitrogen (e.g., BN), or the like. In an embodiment, the deposition process may result in the mask layer depositing along the top surface of the glass core. Additionally, an amount of the mask layer may deposit on the sidewalls of the via openings proximate to a top of the via openings. This portion of the mask layer may persist into the final structure and be a residual indicator that a process similar to embodiments disclosed herein were used to manufacture the product.

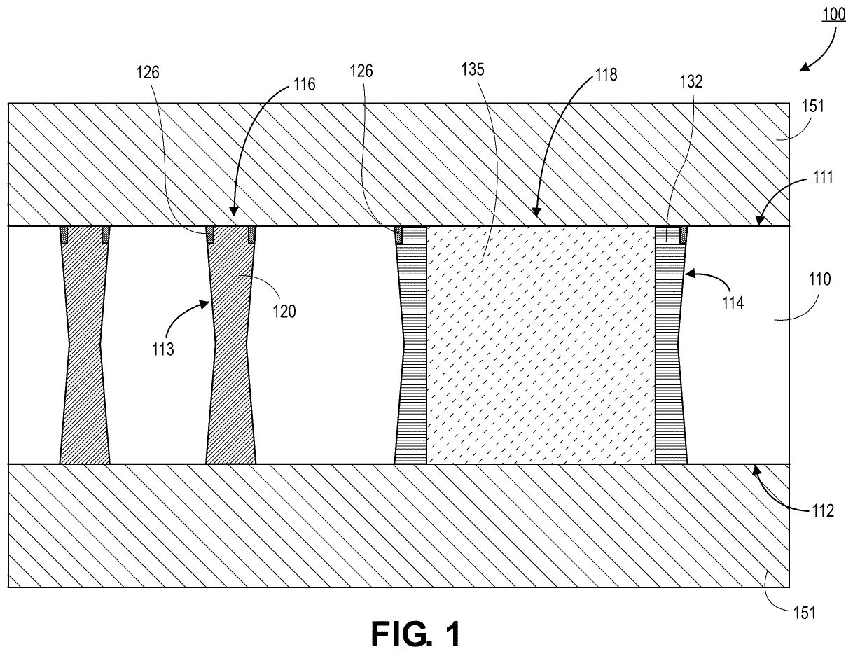

Referring now to FIG. 1, a cross-sectional illustration of a package substrate 100 is shown, in accordance with an embodiment. In an embodiment, the package substrate 100 may comprise a core 110. In a particular embodiment, the core 110 is a glass core 110. In an embodiment, the glass core 110 may be substantially all glass. The glass core 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 110 may be distinguished from, for example, the “prepreg” or “FR4” core of a Printed Circuit Board (PCB) substrate which typically comprises glass fibers embedded in a resinous organic material, such as an epoxy.

The glass core 110 may have any suitable dimensions. In a particular embodiment, the glass core 110 may have a thickness that is approximately 50 μm or greater. For example, the thickness of the glass core 110 may be between approximately 50 μm and approximately 1.4 mm. Though, smaller or larger thicknesses may also be used. The glass core 110 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 110 (from an overhead plan view) may be between approximately 10 mm×10 mm and approximately 250 mm×250 mm. In an embodiment, the glass core 110 may have a first side that is perpendicular or orthogonal to a second side. In a more general embodiment, the glass core 110 may comprise a rectangular prism volume with sections (e.g., vias) removed and filled with other materials (e.g., metal, etc.).

The glass core 110 may comprise a single monolithic layer of glass. In other embodiments, the glass core 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 110 may each have a thickness less than approximately 50 μm. For example, discrete layers of glass in the glass core 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 110 may be any suitable glass formulation that has the necessary mechanical robustness and compatibility with semiconductor packaging manufacturing and assembly processes. For example, the glass core 110 may comprise aluminosilicate glass, borosilicate glass, alumino-borosilicate glass, silica, fused silica, or the like. In some embodiments, the glass core 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 110 may comprise at least 23 percent silicon (by weight) and at least 26 percent oxygen (by weight). In some embodiments, the glass core 110 may further comprise at least 5 percent aluminum (by weight).

In an embodiment, the glass core 110 may comprise one or more through glass vias (TGVs) 120. The TGVs 120 may be provided through a thickness of the glass core 110 from a top surface 111 to a bottom surface 112. The TGVs 120 may be formed in via openings 116. The via openings 116 may have sidewalls 113. In the illustrated embodiment, the sidewalls 113 have a double tapered profile to provide an hourglass shaped cross-section to the TGVs 120. Though, the sidewalls 113 may have any other profile, depending on the process used to form the via openings 116. For example, the sidewalls 113 may be sloped, curved, substantially vertical, or the like. The via openings 116 may be high aspect ratio features. For example, an aspect ratio of the via openings 116 may be approximately 10:1 or greater, approximately 20:1 or greater, or approximately 50:1 or greater.

In an embodiment, the TGVs 120 are formed with a bottom-up plating process, as will be described in greater detail below. Accordingly, the TGVs 120 may not be spaced apart from the sidewall 113 of the via opening 116 by a seed layer. Though, a residual layer 126 may be provided at an end of the TGV 120 between the TGV 120 and the sidewall 113. For example, the residual layer 126 may extend from the top surface 111 down a partial length of the sidewall 113 of the via opening 116 that is less than ten percent of a thickness of the glass core 110 (e.g., less than ten percent of a height of the TGV 120). The residual layer 126 may comprise an electrically insulating material, such as silicon oxide, silicon nitride, titanium oxide, tantalum oxide, aluminum oxide, boron nitride, or the like.

In an embodiment, a cavity 118 may also be formed through a thickness of the glass core 110. In an embodiment, the cavity 118 may comprise sidewalls 114. The profile of the sidewalls 114 may be similar to the profile of the sidewalls 113. For example, the cavity 118 and the via openings 116 may be formed with similar processes. In an embodiment, the cavity 118 may be a low aspect ratio feature. For example, an aspect ratio of the cavity 118 may be up to approximately 10:1, or up to approximately 5:1, or up to approximately 2:1.

In an embodiment, a component 135 may be provided within the cavity 118. In an embodiment, the component 135 may comprise a passive electrical component (e.g., a capacitor, an inductor, a resistor, etc.), an active components (e.g., a die, memory, etc.), electrical routing (e.g., a bridge substrate, etc.), or the like. The component 135 may be a discrete component, or the component 135 may be integrated into the cavity 118 as part of the overall process flow. While a single component 135 is shown in the cavity 118, it is to be appreciated that a plurality of cavities may be provided within the cavity 118.

In an embodiment, the component 135 may be embedded with a dielectric fill material 132. In some embodiments, the dielectric fill material 132 comprises an organic dielectric material, an epoxy, or the like. The dielectric fill material 132 may also comprise an organic buildup film similar to (or the same as) an organic buildup film used to form the buildup layers 151 over and under the glass core 110.

In an embodiment, residual layers 126 may also be provided at the upper end of the cavity 118 along the sidewalls 114. The residual layers 126 in the cavity 118 may be similar to the residual layers 126 that line upper ends of the TGVs 120 described previously. For example, the residual layers 126 in the cavity 118 may comprise an electrically insulating material and extend into the cavity 118 from the top surface 111 of the glass core 110 to a depth up to approximately ten percent of the thickness of the glass core 110. That is, a height of the residual layer is less than a height of the glass core 110 in some embodiments. Though, in other embodiments, the residual layer 126 along the sidewalls 114 may cover substantially the entire sidewall 114. The lower aspect ratio of the cavity 118 may allow for more sidewall 114 coverage by the residual layer 126 compared to the sidewalls 113 of the via openings 116.

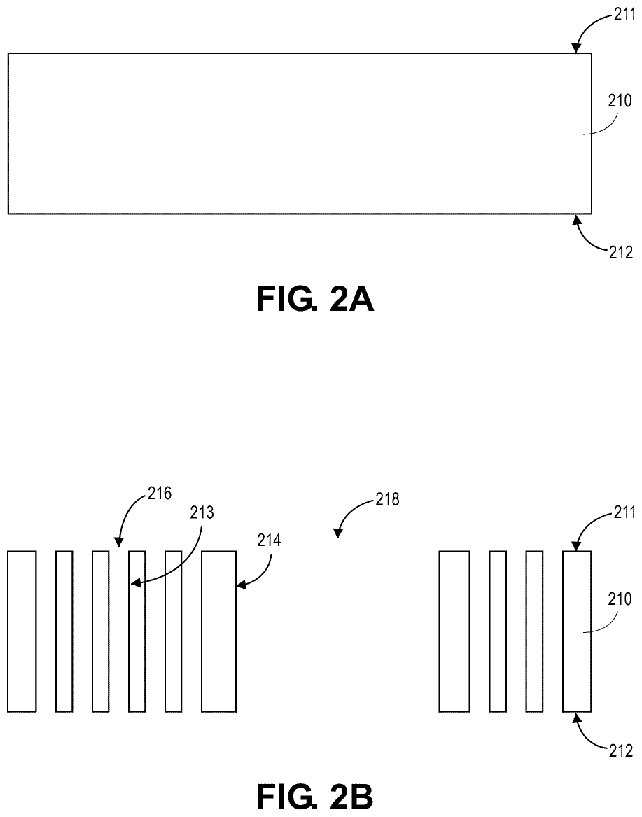

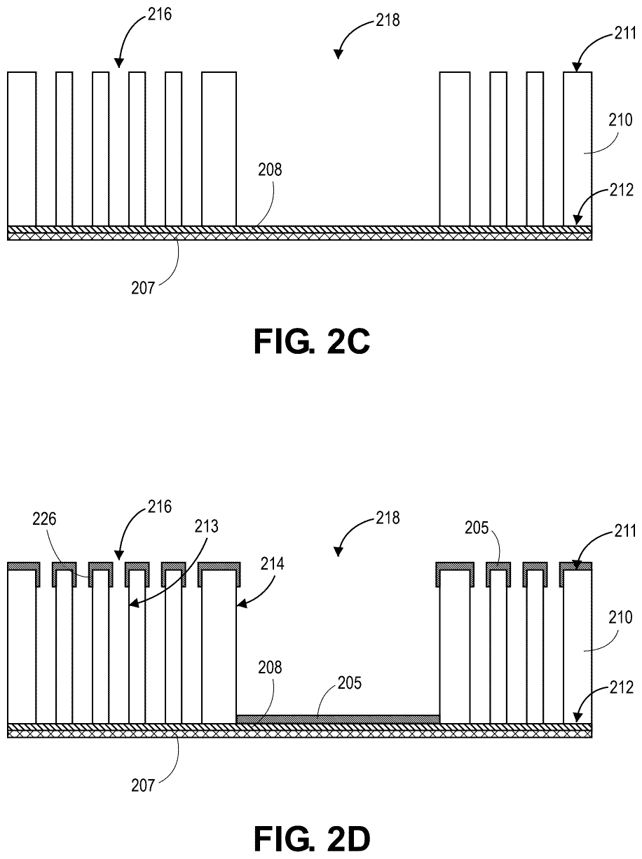

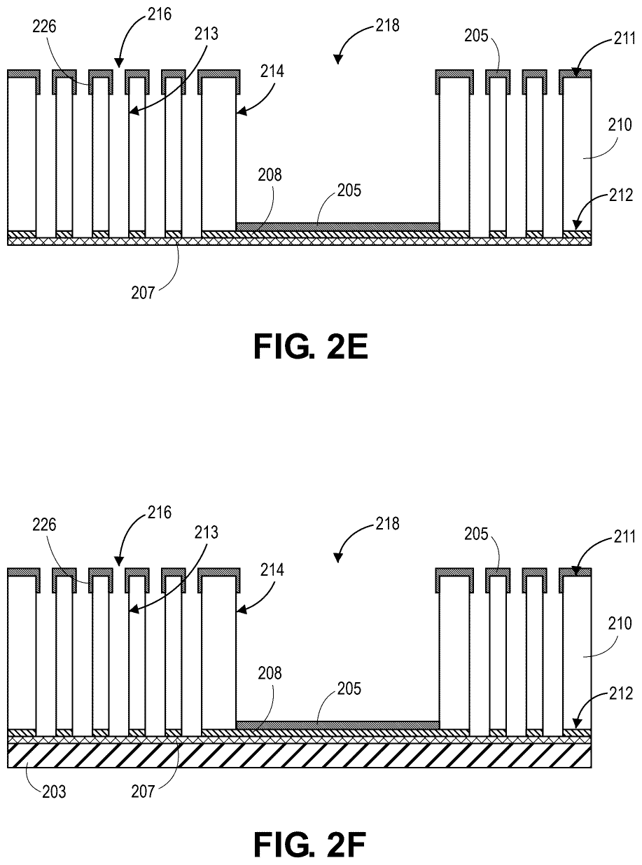

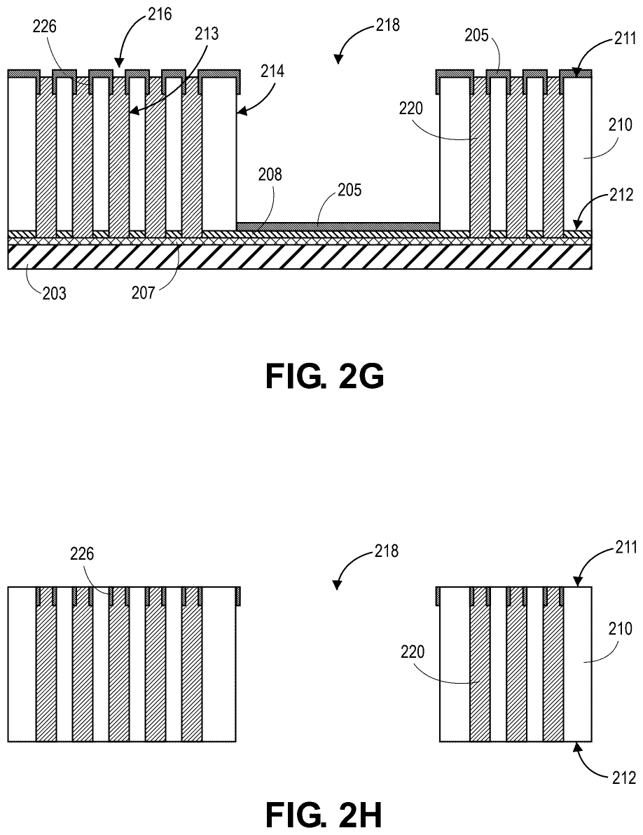

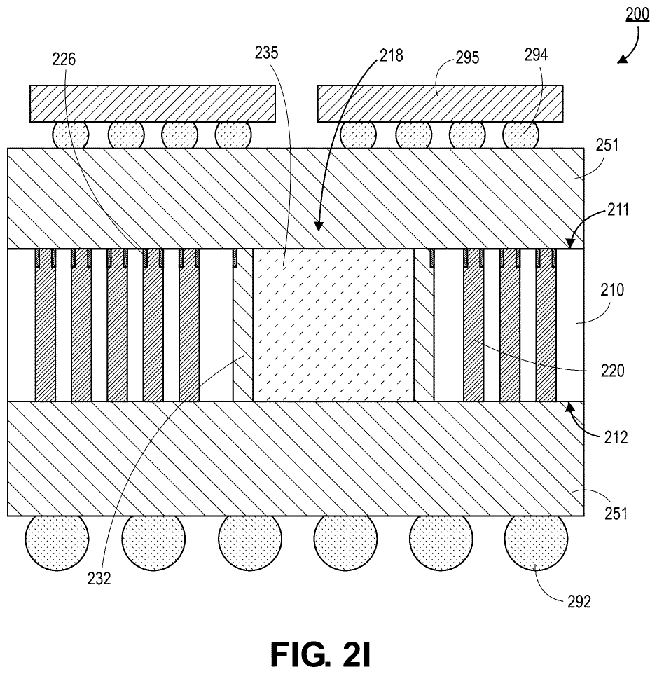

Referring now to FIGS. 2A-2I , a series of cross-sectional illustrations depicting a process for forming a glass core with TGVs that are formed with a bottom-up plating process with an un-filled adjacent cavity is shown, in accordance with an embodiment.

Referring now to FIG. 2A, a cross-sectional illustration of a portion of a glass core 210 is shown, in accordance with an embodiment. In an embodiment, the glass core 210 may be similar to any of the glass cores described in greater detail herein. In an embodiment, the glass core 210 may have a panel form factor or any other suitable form factor, including a unit form factor.

Referring now to FIG. 2B, a cross-sectional illustration of a portion of the glass core 210 after via openings 216 and a cavity 218 are formed through a thickness of the glass core 210 is shown, in accordance with an embodiment. In an embodiment, the via openings 216 and the cavity 218 may pass through the thickness of the glass core 210 from the top surface 211 to the bottom surface 212. In the illustrated embodiment, sidewalls 213 of the via openings 216 and sidewalls 214 of the cavity 218 are substantially vertical. Though, it is to be appreciated that the sidewalls 213 and 214 may have any suitable profile, depending on the process used to form the via openings 216 and the cavity 218. In an embodiment, the via openings 216 and the cavity 218 are formed with a laser assisted etching process. Though, any suitable subtractive process may be used in accordance with other embodiments.

Referring now to FIG. 2C, a cross-sectional illustration of the glass core 210 after a conductive film 207 is attached to the bottom surface 212 of the glass core 210 with an adhesive 208 is shown, in accordance with an embodiment. In an embodiment, the conductive film 207 may comprise a copper film or the like, The adhesive 208 and the conductive film 207 may span across bottoms of the via openings 216 and the cavity 218. The conductive film 207 and the adhesive 208 may be applied with a lamination process or the like.

Referring now to FIG. 2D, a cross-sectional illustration of the glass core 210 after a mask layer 205 is applied over the glass core 210 is shown, in accordance with an embodiment. The mask layer 205 may be applied with a PVD process that allows for the mask layer to selectively deposit along the adhesive 208 at the bottom of the cavity 218. For example, the high aspect ratio of the via openings 216 substantially prevents the mask layer 205 from reaching the bottom of the via openings 216. In an embodiment, the mask layer 205 may also deposit along the top surface 211 of the glass core 210. Additionally, a portion 226 of the mask layer 205 may deposit along the upper sidewalls 213 and 214 of the via openings 216 and cavities 218, respectively. The portion 226 may sometimes be referred to as a residual layer 226, since the portion 226 may persist into the final structure of the devices, as will be described in greater detail herein. In an embodiment, the portion 226 may extend down into the via openings 216 and/or the cavities 218 to a depth up to approximately ten percent of a thickness of the glass core 210. Though, the depth that the portion 226 extends to within the glass core 210 may be greater in some embodiments.

In an embodiment, the mask layer 205 comprises a material that is etch selective to the adhesive 208. Additionally, the mask layer 205 is an electrically insulating material so that no plating occurs from the mask layer 205 during the bottom-up plating process. For example, the mask layer 205 may comprise silicon oxide, silicon nitride, titanium oxide, tantalum oxide, aluminum oxide, boron nitride, or the like.

In the illustrated embodiment, the deposition of the mask layer 205 leaves the via openings 116 accessible. However, in some embodiments, the mask layer 205 may grow together and close off the via openings 116. In such an embodiment, a quick etching process (e.g., a flash etch) may be used to reopen the via openings 116.

Referring now to FIG. 2E, a cross-sectional illustration of the glass core 210 after an etching process is used to clear the adhesive 208 from the bottom of the via openings 216 is shown, in accordance with an embodiment. In an embodiment, the etching process may be a reactive ion etching process (RIE) or the like. The removal of the adhesive 208 exposes the underlying conductive layer 207 to allow for bottom-up plating within the via openings 216. However, the mask layer 205 protects the adhesive 208 within the cavities 218. As such, the subsequent bottom-up plating process will not plate copper within the cavities 218.

Referring now to FIG. 2F, a cross-sectional illustration of the glass core 210 after an insulating layer 203 is provided over a backside of the conductive layer 207 is shown, in accordance with an embodiment. The insulating layer 203 may be applied with a lamination process or the like. In an embodiment, the insulating layer 203 prevents plating from the backside of the conductive layer 207 during the bottom-up plating process.

Referring now to FIG. 2G, a cross-sectional illustration of the glass core 210 after the bottom-up plating process is used to form the TGVs 220 is shown, in accordance with an embodiment. As shown, the TGVs 220 plate up from the conductive layer 207 exposed at the bottom of the via openings 216. The TGVs 220 may plate up and cover portions 226 of the mask layer 205. A more detailed description of the bottom-up plating process is described in greater detail below.

Referring now to FIG. 2H, a cross-sectional illustration of the glass core 210 after the insulating layer 203, the conductive layer 207, and the adhesive 208 are removed is shown, in accordance with an embodiment. Additionally, a polishing process may be used to clear the mask layer 205 from the surfaces of the glass core 210. However, since the residual layers 226 are within the thickness of the glass core 210 (and protected by the TGVs 220), the residual layers 226 may persist in the structure of the glass core 210.

Referring now to FIG. 2I, a cross-sectional illustration of the portion of a the glass core 210 after the glass core 210 is integrated into a package substrate 200 is shown, in accordance with an embodiment. As shown, the package substrate 200 in FIG. 2I may be similar to the package substrate 100 in FIG. 1. For example, a component 235 may be inserted (or fabricated) into the cavity 218, and the cavity 218 is filled with a dielectric fill material 232. Buildup layers 251 with electrical routing (not shown) may be provided over and under the glass core 210. In an embodiment, second level interconnects (SLIs) 292 may be provided at a bottom of the buildup layers 251 below the glass core 210, and first level interconnects (FLIs) 294 may electrically couple the upper buildup layers 251 to one or more dies 295.

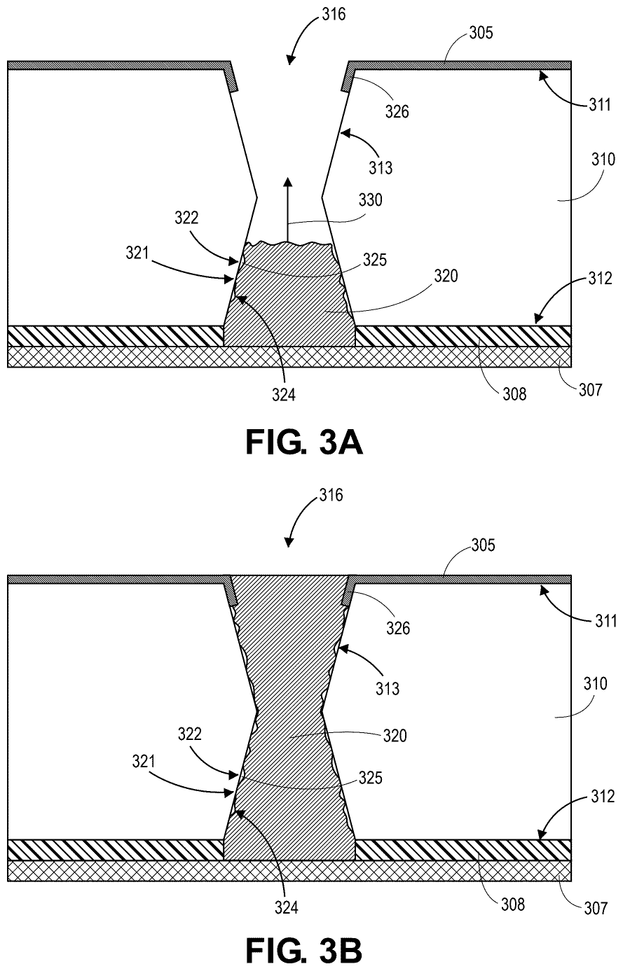

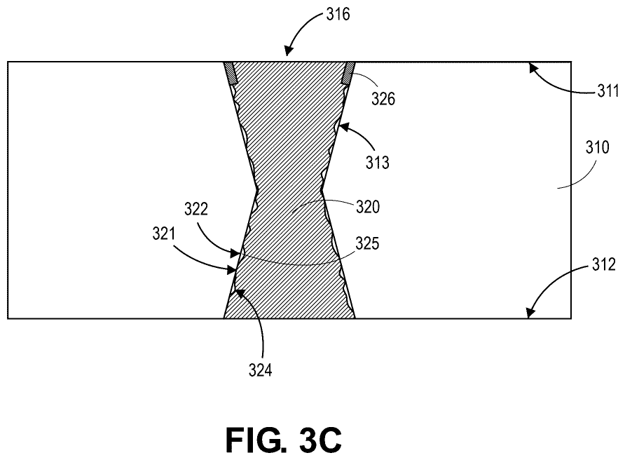

Referring now to FIGS. 3A-3C , a series of cross-sectional illustrations depicting a process for forming a TGV in a glass core with a bottom-up plating process is shown, in accordance with an embodiment.

Referring now to FIG. 3A, a cross-sectional illustration of a glass core 310 is shown, in accordance with an embodiment. In an embodiment, a via opening 316 is provided through a thickness of the glass core 310. The via opening 316 may be formed with any suitable process. For example, a laser assisted etching process may be used to form the via opening 316 in some embodiments. In an embodiment, the via opening 316 may be a high aspect ratio via opening 316. For example, an aspect ratio (height:width) of the via opening 316 may be 10:1 or greater, 20:1 or greater, or 50:1 or greater. Though, embodiments may also be used with smaller aspect ratio via openings 316 as well.

In the illustrated embodiment, sidewalls 313 of the via opening 316 have a slope relative to a top surface 311 and a bottom surface 312 of the glass core 310. The via opening 316 may have sidewalls 313 that form an hourglass shape. Though, in other embodiments, the sidewalls 313 may have a single slope to form a via opening 316 with a single taper. In other embodiments, the sidewalls 313 may be substantially vertical (i.e., orthogonal to the top surface 311), the sidewalls 313 may be curved (e.g., non-planar), or have any other suitable profile.

In an embodiment, a conductive layer 307 may be attached to the bottom surface 312 of the glass core 310 by an adhesive 308. In an embodiment, a portion of the adhesive 308 below the via opening 316 has been removed with an etching process, similar to the process described above with respect to FIGS. 2D and 2E. For example, a portion of the mask layer 305 may be on the top surface 311 of the glass core 310, and the residual portion 326 may extend down the sidewall 313 of the via opening 316 from the top surface 311 of the glass core 310. As shown, the conductive layer 307 may span across the via opening 316. As such, a portion of the conductive layer 307 is exposed by the via opening 316 in order to allow for the bottom-up plating process described in greater detail herein.

As indicated by the arrow 330, the plating of the TGV 320 extends in a vertical direction from the conductive layer 307 in a bottom-up manner. The plating may be any suitable electroplating process. Due to the bottom-up plating process, the sidewalls 324 of the TGV 320 may have a textured surface that interfaces with the sidewall 313 of the via opening 316. For example, the sidewalls 324 may be non-linear with peaks and valleys. In an embodiment, the sidewall 324 of the TGV 320 may directly contact the sidewall 313 of the via opening 316 at a first location 321, and the sidewall 324 of the TGV 320 may be spaced away from the sidewall of the via opening 316 by a gap 325 at a second location 322.

In an embodiment, the TGV 320 directly contacting the sidewall 313 of the via opening 316 may refer to there being no intermediary layer between the TGV 320 and the sidewall 313. For example, in existing plating processes, a seed layer or the like may be provided between the sidewall 313 of the via opening 316 and the sidewall 324 of the TGV 320. In an embodiment, the gap 325 may have any suitable dimension. For example, a width of the gap 325 between the sidewall 313 of the via opening 316 and the sidewall 324 of the TGV 320 may be up to approximately 5 μm, up to approximately 1 μm, up to approximately 0.5 μm, or up to approximately 0.1 μm. As noted above, the presence of the gaps 325 allows for weaker mechanical coupling between the TGV 320 and the glass core 310. Accordingly, stress related to coefficient of thermal expansion (CTE) mismatch between the glass core 310 and the TGV 320 may be mitigated, and the mechanical robustness of the glass core 310 is improved.

Referring now to FIG. 3B, a cross-sectional illustration of the glass core 310 after the plating of the TGV 320 is completed is shown, in accordance with an embodiment. As shown, the TGV 320 substantially fills the via opening, with the exception of the presence of gaps 325 at some locations along the height of the TGV 320. Further, the TGV 320 may surround (and directly contact) the residual portions 326 of the mask layer 305. In a particular embodiment, a cross-sectional area of the TGV 320 along a plane (e.g., the plane illustrated in FIG. 3B) may be smaller than a cross-sectional area of the via opening 316 along the same plane. In an embodiment, the difference between the cross-sectional areas of the via opening 316 and the TGV 320 may be occupied by the cross-sectional area of all of the gaps 325. In an embodiment, the cross-sectional area of the TGV 320 along the plane may be approximately 95% or more of the cross-sectional area of the via opening 316, approximately 99% or more of the cross-sectional area of the via opening 316, approximately 99.5% or more of the cross-sectional area of the via opening 316, or approximately 99.9% or more of the cross-sectional area of the via opening. Stated differently, the via opening 316 may be substantially filled with only the TGV 320, and any remaining area of the via opening 316 may be occupied by gaps 325 (e.g., air gaps) between the sidewall 313 of the via opening 316 and the sidewall 324 of the TGV 320.

In an embodiment, the TGV 320 may comprise a substantially uniform composition across a line from a first edge of the TGV 320 to a second edge of the TGV 320 that is parallel to the top surface 311 or the bottom surface 312 of the glass core 310. For example, the TGV 320 may have a substantially uniform composition comprising copper. This is different than many existing via architectures that include a seed layer along the sidewall 313 of the via opening 316. In such an embodiment, the via may have a different composition along the outer edge of the via due to the seed layer. For example, concentrations of titanium or other seed layer materials may be present at the edge of the via. However, embodiments disclosed herein may comprise a substantially uniform composition from edge-to-edge since a bottom-up plating process is used.

Referring now to FIG. 3C, a cross-sectional illustration of the glass core 310 after the conductive layer 307, the adhesive 308, and the mask layer 305 are removed is shown, in accordance with an embodiment. In an embodiment, the layers may be removed with one or more of an etching process, a polishing process, or the like. Due to the presence of the conductive layer 307, the bottom surface of the TGV 320 may be substantially flat and coplanar with the bottom surface 312 of the glass core 310. In some embodiments, the top surface of the TGV 320 may be polished or planarized so that the top surface is substantially flat and coplanar with the top surface 311 of the glass core 310. As shown, the residual portion 326 persists into the final structure of the glass core 310.

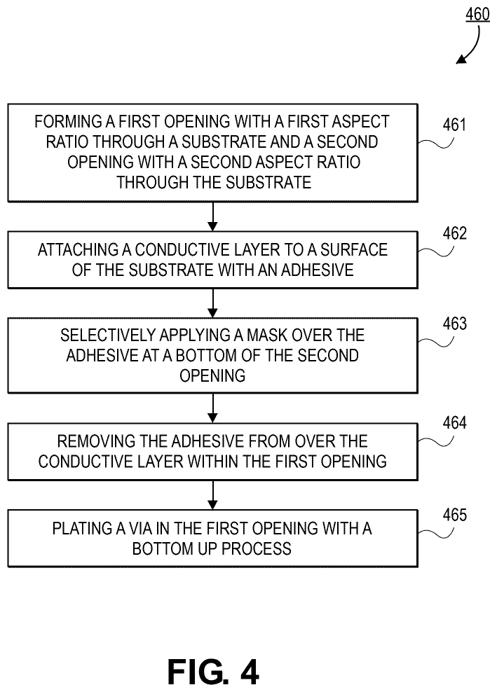

Referring now to FIG. 4, a flow diagram depicting a process 460 for forming a glass core with bottom-up plated vias and an cavity that is free from plating is shown, in accordance with an embodiment. In an embodiment, the process 460 may be similar to (or include operations similar to) any of the process flows described in greater detail herein with respect to FIGS. 2A-2I and/or 3A-3C.

In an embodiment, the process 460 may begin with operation 461, which comprises forming a first opening with a first aspect ratio through a substrate, and a second opening with a second aspect ratio through the substrate. In an embodiment, the substrate is a glass core, similar to any of the glass cores described in greater detail herein. In an embodiment, the first aspect ratio is larger than the second aspect ratio. For example, the first aspect ratio may be approximately 10:1 or greater, approximately 20:1 or greater, or approximately 50:1 or greater, and the second aspect ratio may be approximately 10:1 or smaller, approximately 5:1 or smaller, or approximately 2:1 or smaller. In an embodiment, the first opening may be referred to as a via opening, and the second opening may be referred to as a cavity.

In an embodiment, the process 460 may continue with operation 462, which comprises attaching a conductive layer to a surface of the substrate with an adhesive. In an embodiment, the conductive layer may comprise copper or any other suitable conductive seed layer material. The adhesive and the conductive layer may span across the first opening and the second opening.

In an embodiment, the process 460 may continue with operation 463, which comprises selectively applying a mask over the adhesive at a bottom of the second opening. In an embodiment, the mask is selectively applied with a PVD process that leverages the difference in aspect ratios between the first opening and the second opening. That is, the mask layer may not deposit along the adhesive at the bottom of the first opening due to the high aspect ratio. During the deposition of the mask layer, residual portions of the mask layer may deposit along the upper sidewalls of the first opening and/or the second opening.

In an embodiment, the process 460 may continue with operation 464, which comprises removing the adhesive from over the conductive layer within the first opening. In an embodiment, an etching process (e.g., a RIE process) may be used to selectively remove the adhesive in the first opening. This exposes the underlying conductive layer in the first opening. The mask layer protects the adhesive in the second opening.

In an embodiment, the process 460 may continue with operation 465, which comprises plating a via in the first opening with a bottom-up plating process. In an embodiment, the bottom-up plating process may be similar to the process described above with respect to FIGS. 3A-3C. After the plating process, the adhesive layer, the conductive layer, and the mask layer may be removed from the substrate. However, the residual portion of the mask layer may persist in the substrate. For example, the residual portion of the mask layer may be surrounded by the via in some embodiments.

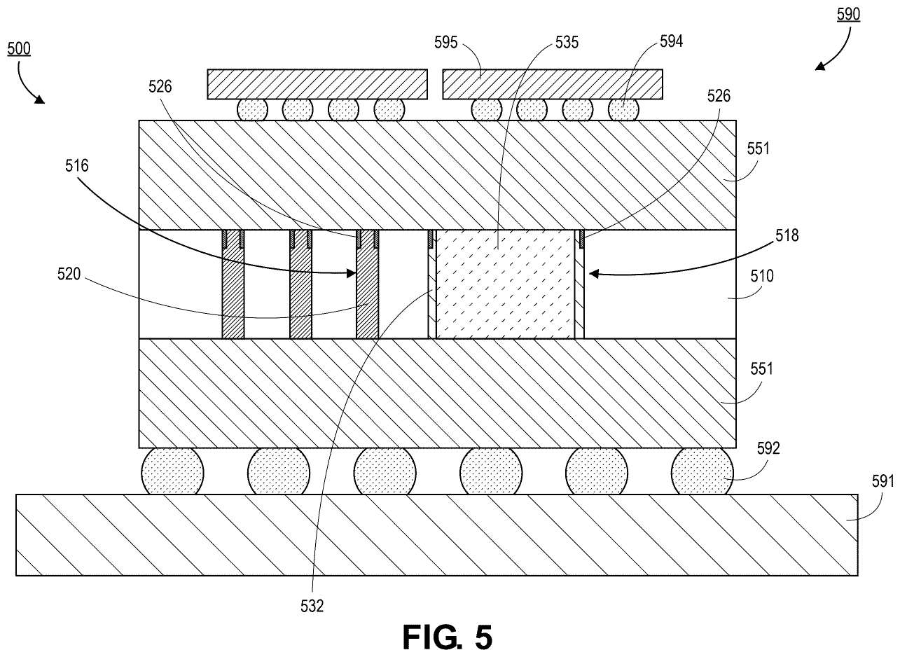

Referring now to FIG. 5, a cross-sectional illustration of an electronic system 590 is shown, in accordance with an embodiment. In an embodiment, the electronic system 590 may comprise a board 591, such as a printed circuit board (PCB), a motherboard, or the like. In an embodiment, the board 591 may be coupled to a package substrate 500 by SLIs 592. In an embodiment, the SLIs 592 may comprise solder balls, sockets, or the like.

In an embodiment, the package substrate 500 may be similar to any of the package substrates described in greater detail herein. In an embodiment, the package substrate 500 may comprise a glass core 510 with TGVs 520. The TGVs 520 may be formed with a bottom-up plating process such as any of those described in greater detail herein. In an embodiment, the TGVs 520 may have a textured surface that allows for a reduction in an amount of stress that is induced in the glass core 510 due to weaker mechanical coupling compared to existing plating processes. The TGVs 520 may be similar to any of the TGVs described in greater detail herein. For example, an upper end of the TGVs 520 may be spaced away from the sidewall of the via opening 516 by a residual portion 526 of a mask layer. In an embodiment, glass core 510 may comprise a cavity 518 that houses a component 535. A dielectric fill material 532 may surround the component 535. In an embodiment, the package substrate 500 may also comprise buildup layers 551 that are provided over and under the glass core 510.

In an embodiment, one or more dies 595 may be coupled to the buildup layer 551 by FLIs 594. The FLIs 594 may be any suitable FLI architecture, such as solder balls, copper bumps, hybrid bonding interfaces, or the like. In an embodiment, the one or more dies 595 may be any type of die (e.g., a processor die (e.g., a central processing unit (CPU), a graphics processing unit (GPU), an XPU), a memory die, a communications die, a power management die, and/or the like). In an embodiment, two or more dies 595 may be electrically coupled together by a bridge (not shown) that is embedded in the buildup layer 551 or provided over the buildup layer 551.

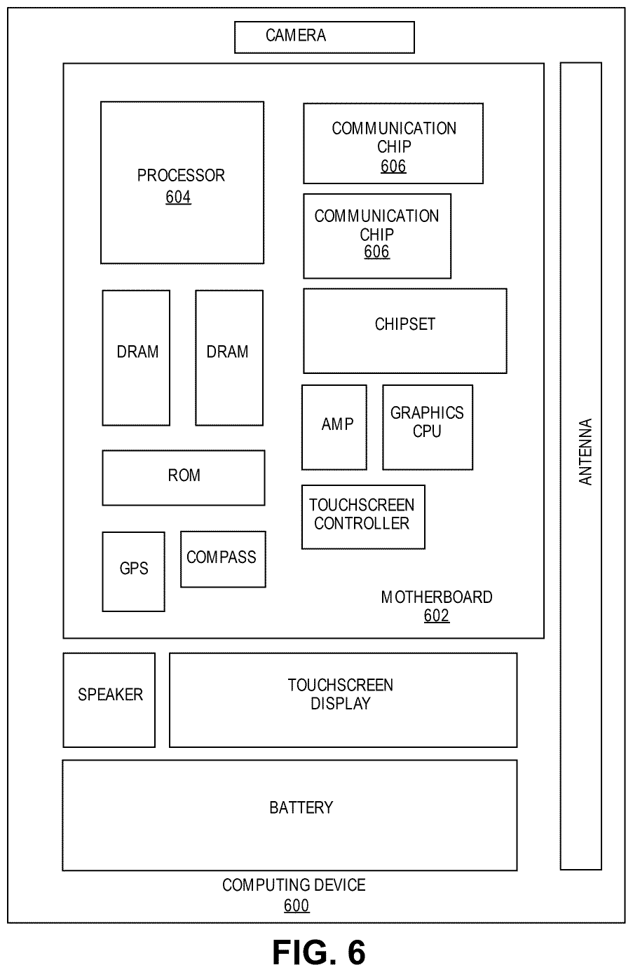

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604. In an embodiment, a device package is coupled to the board 602. One or both of the processor 604 or the communication chip 606 may be coupled to the board 602 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of a package substrate with a glass core that comprises TGVs that are formed with a bottom-up plating process with an unfilled cavity, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of a package substrate with a glass core that comprises TGVs that are formed with a bottom-up plating process with an unfilled cavity, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate, wherein the substrate comprises a glass layer; a via through a thickness of the substrate, wherein the via has a first aspect ratio, wherein the via directly contacts the substrate; a layer around an end of the via, wherein the layer extends down a partial length of a sidewall of the via; a cavity through the thickness of the substrate, wherein the cavity has a second aspect ratio that is smaller than the first aspect ratio; a component in the cavity; and a fill layer around the component in the cavity.

Example 2: the apparatus of Example 1, wherein the partial length of the sidewall of the via is less than ten percent of a height of the via.

Example 3: the apparatus of Example 1 or Example 2, wherein the layer comprises a dielectric material.

Example 4: the apparatus of Examples 1-3, wherein the layer comprises silicon and oxygen, silicon and nitrogen, titanium and oxygen, tantalum and oxygen, aluminum and oxygen, or boron and nitrogen.

Example 5: the apparatus of Examples 1-4, wherein the component comprises a passive electrical component.

Example 6: the apparatus of Example 5, wherein the passive electrical component comprises a capacitor or an inductor.

Example 7: the apparatus of Examples 1-6, wherein the component is a discrete component.

Example 8: the apparatus of Examples 1-7, further comprising: a second layer on a sidewall of the cavity.

Example 9: the apparatus of Examples 1-8, further comprising: an organic buildup film over the substrate.

Example 10: the apparatus of Example 9, further comprising: a die coupled to the organic buildup film; and a board coupled to the substrate.

Example 11: a method, comprising: attaching a conductive layer to a surface of a substrate with an adhesive, wherein a first opening with a first aspect ratio is formed through the substrate and a second opening with a second aspect ratio is formed through the substrate, and wherein the second aspect ratio is smaller than the first aspect ratio; selectively applying a mask over the adhesive at a bottom of the second opening; removing the adhesive from over the conductive layer within the first opening; and plating a via in the first opening with a bottom up process.

Example 12: the method of Example 11, wherein the mask comprises an electrically insulating material.

Example 13: the method of Example 12, wherein the mask comprises silicon and oxygen, silicon and nitrogen, titanium and oxygen, tantalum and oxygen, aluminum and oxygen, or boron and nitrogen.

Example 14: the method of Examples 11-13, wherein the mask is applied with a physical vapor deposition process.

Example 15: the method of Examples 11-14, wherein the first aspect ratio (height:width) is 10:1 or greater.

Example 16: the method of Examples 11-15, wherein the via directly contacts the substrate within the first opening.

Example 17: the method of Examples 11-16, wherein the adhesive is removed with a reactive ion etching process.

Example 18: an apparatus, comprising: a substrate, wherein the substrate comprises a glass layer; a via through a thickness of the glass layer, wherein the via directly contacts the substrate at a location; and a layer between the substrate and the via at an end of the via, wherein a height of the layer is less than a height of the via.

Example 19: the apparatus of Example 18, wherein the layer is electrically insulating.

Example 20: the apparatus of Example 18 or Example 19, further comprising: an air gap between the substrate and the via at a second location.

What is claimed is:

1. An apparatus, comprising:
a substrate, wherein the substrate comprises a glass layer;
a via through a thickness of the substrate, wherein the via has a first aspect ratio, wherein the via directly contacts the substrate;
a layer around an end of the via, wherein the layer extends down a partial length of a sidewall of the via;
a cavity through the thickness of the substrate, wherein the cavity has a second aspect ratio that is smaller than the first aspect ratio;
a component in the cavity; and
a fill layer around the component in the cavity.

2. The apparatus of claim 1, wherein the partial length of the sidewall of the via is less than ten percent of a height of the via.

3. The apparatus of claim 1, wherein the layer comprises a dielectric material.

4. The apparatus of claim 1, wherein the layer comprises silicon and oxygen, silicon and nitrogen, titanium and oxygen, tantalum and oxygen, aluminum and oxygen, or boron and nitrogen.

5. The apparatus of claim 1, wherein the component comprises a passive electrical component.

6. The apparatus of claim 5, wherein the passive electrical component comprises a capacitor or an inductor.

7. The apparatus of claim 1, wherein the component is a discrete component.

8. The apparatus of claim 1, further comprising:
a second layer on a sidewall of the cavity.

9. The apparatus of claim 1, further comprising:
an organic buildup film over the substrate.

10. The apparatus of claim 9, further comprising:
a die coupled to the organic buildup film; and
a board coupled to the substrate.

11. A method, comprising:
attaching a conductive layer to a surface of a substrate with an adhesive, wherein a first opening with a first aspect ratio is formed through the substrate and a second opening with a second aspect ratio is formed through the substrate, and wherein the second aspect ratio is smaller than the first aspect ratio;
selectively applying a mask over the adhesive at a bottom of the second opening;
removing the adhesive from over the conductive layer within the first opening; and
plating a via in the first opening with a bottom up process.

12. The method of claim 11, wherein the mask comprises an electrically insulating material.

13. The method of claim 12, wherein the mask comprises silicon and oxygen, silicon and nitrogen, titanium and oxygen, tantalum and oxygen, aluminum and oxygen, or boron and nitrogen.

14. The method of claim 11, wherein the mask is applied with a physical vapor deposition process.

15. The method of claim 11, wherein the first aspect ratio (height:width) is 10:1 or greater.

16. The method of claim 11, wherein the via directly contacts the substrate within the first opening.

17. The method of claim 11, wherein the adhesive is removed with a reactive ion etching process.

18. An apparatus, comprising:
a substrate, wherein the substrate comprises a glass layer;
a via through a thickness of the glass layer, wherein the via directly contacts the substrate at a location; and
a layer between the substrate and the via at an end of the via, wherein a height of the layer is less than a height of the via.

19. The apparatus of claim 18, wherein the layer is electrically insulating.

20. The apparatus of claim 18, further comprising:
an air gap between the substrate and the via at a second location.
